(19) United States
(12) Patent Application Publication
(10) Pub. No.: US 2026/0165030 A1
(43) Pub. Date: Jun. 11, 2026

(54) MAGNETIC MEMORY DEVICE AND METHOD FOR MANUFACTURING THE SAME

(71) Applicant: SAMSUNG ELECTRONICS CO., LTD., Suwon-si (KR)

(72) Inventors: Yong Sung Park, Suwon-si (KR); Jeong Mok Kim, Suwon-si (KR); Young Hyun Kim, Suwon-si (KR); Jeong-Heon Park, Suwon-si (KR); Yoon Young Lee, Suwon-si (KR)

(73) Assignee: SAMSUNG ELECTRONICS CO., LTD., Suwon-si (KR)

(21) Appl. No.: 19/324,935

(22) Filed: Sep. 10, 2025

(30) Foreign Application Priority Data
Dec. 10, 2024 (KR) 10-2024-0182778

(51) Int. Cl. H10N 50/01; H10B 61/00; H10N 50/10; H10N 50/85

(52) U.S. Cl. CPC H10N 50/01; H10B 61/10; H10N 50/10; H10N 50/85

(57) ABSTRACT

A method for manufacturing a magnetic memory device, may include: providing a seed layer; forming a fixed layer on the seed layer; forming an antiparallel coupling layer including a synthetic antiferromagnetic (SAF) layer, on the fixed layer; forming a tunnel barrier layer; forming a free layer on the tunnel barrier layer; forming a metal layer including a first metal and a second metal, on the free layer; and performing an oxidation process to form a metal oxide layer including an oxide of the second metal. The first metal may have a stronger bonding affinity with boron (B) than the second metal, and the second metal may have a stronger bonding affinity with oxygen (O) than the first metal.

### CROSS-REFERENCE TO RELATED APPLICATION

This application claims priority from Korean Patent Application No. 10-2024-0182778 filed on Dec. 10, 2024 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a magnetic memory device and a method for manufacturing the same.

### 2. Description of the Related Art

As electronic devices have become faster and more power-efficient, memory devices embedded therein also perform fast read/write operations and operate at low voltages. Magnetic memory devices can be used in such applications. Magnetic memory devices are non-volatile and capable of high-speed operation, making them promising candidates for next-generation memories.

Meanwhile, as magnetic memory elements become increasingly integrated, spin transfer torque (STT)-magnetic random-access memories (STT-MRAMs), which store information using the STT phenomenon, have been actively researched. STT-MRAMs store information by inducing magnetization reversal through the application of direct current to magnetic tunnel junction (MTJ) devices. Highly integrated STT-MRAMs are operated at high-speed and low-current.

### SUMMARY

A technical problem that may be solved by embodiments of the present disclosure is to provide a method for manufacturing a magnetic memory device with improved reliability and performance.

Another technical problem that may be solved by embodiments of the present disclosure is to provide a magnetic memory device with improved reliability and performance.

The problems addressed by the present disclosure are not limited to those described above, and other problems will be apparent to those skilled in the art from the following descriptions.

According to an aspect of the disclosure, a method for manufacturing a magnetic memory device, may include: providing a seed layer; forming a fixed layer on the seed layer; forming an antiparallel coupling layer including a synthetic antiferromagnetic (SAF) layer, on the fixed layer; forming a tunnel barrier layer; forming a free layer on the tunnel barrier layer; forming a metal layer including a first metal and a second metal, on the free layer; and performing an oxidation process to form a metal oxide layer including an oxide of the second metal. The first metal may have a stronger bonding affinity with boron (B) than the second metal, and the second metal may have a stronger bonding affinity with oxygen (O) than the first metal.

According to an aspect of the disclosure, a magnetic memory device may include: a magnetic tunnel junction (MTJ) including a first fixed layer and a second fixed layer sequentially stacked on a seed layer, an antiparallel coupling layer including a synthetic antiferromagnetic (SAF) layer, between the first fixed layer and the second fixed layer, a tunnel barrier layer on the second fixed layer, a free layer on the tunnel barrier layer, a metal oxide layer in contact with the free layer, on the free layer, and a capping layer on the metal oxide layer, the metal oxide layer includes first and second metal materials that are different from each other, the first metal material has a stronger bonding affinity with boron (B) than the second metal material, the second metal material has a stronger bonding affinity with oxygen (O) than the first metal material, and a content of the second metal material is at least 5% relative to a content of the first metal material.

The first metal material may include tantalum (Ta).

The second metal material may include iron (Fe).

The metal oxide layer may further include a third metal material different from the first and second metal materials, and a content of the second metal material may be greater than a content of the third metal material.

The third metal material may include cobalt (Co).

A content of the second metal material may be less than a content of the first metal material.

A content of oxygen (O) in the metal oxide layer may be greater than a content of O in the free layer.

The magnetic memory device may further include: a switching unit including a first source/drain region, a second source/drain region, and a gate structure; a first wiring connected to the first source/drain region; a lower electrode connected to the second source/drain region; the MTJ on the lower electrode; an upper electrode on the MTJ; and a second wiring connected to the upper electrode.

According to an aspect of the disclosure, a method for manufacturing a magnetic tunnel junction (MTJ), may include: providing a tunnel barrier layer; forming a free layer on the tunnel barrier layer; forming an iron tantalum (FeTa) layer on the free layer; and performing an oxidation process to form an oxide layer on the FeTa layer, the oxide layer including iron (Fe), tantalum (Ta), and oxygen (O).

According to an aspect of the disclosure, a method for manufacturing a magnetic memory device, may include: providing a seed layer; forming a first fixed layer on the seed layer; forming an antiparallel coupling layer including a synthetic antiferromagnetic (SAF) layer, on the first fixed layer; forming a second fixed layer on the antiparallel coupling layer; forming a tunnel barrier layer on the second fixed layer; forming a free layer including boron (B), on the tunnel barrier layer; forming a metal layer including a first metal and a second metal, on the free layer, wherein the first metal has a stronger bonding affinity with the boron (B) than the second metal and the second metal has a stronger bonding affinity with oxygen (O) than the first metal; performing a heat treatment process to diffuse the B from the free layer into the metal layer; and performing an oxidation process to form a metal oxide layer including an oxide of the second metal.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a block diagram for explaining a magnetic memory device according to one or more embodiments;

FIG. 2 is a circuit diagram illustrating a memory cell array of the magnetic memory device according to one or more embodiments;

FIG. 3 is a schematic diagram illustrating a memory cell of the magnetic memory device according to one or more embodiments;

FIG. 4 is a schematic cross-sectional view illustrating the magnetic memory device according to one or more embodiments;

FIG. 5 is a cross-sectional view illustrating an MTJ of the magnetic memory device according to one or more embodiments;

FIG. 6 is a cross-sectional view illustrating an MTJ of a magnetic memory device according to one or more embodiments;

FIG. 7 is a flowchart illustrating a method for manufacturing a magnetic memory device according to one or more embodiments; and

FIG. 8 is a schematic diagram illustrating a system for manufacturing a magnetic memory device according to one or more embodiments.

### DETAILED DESCRIPTION

In this specification, although terms such as first, second, upper, and lower are used to describe various elements or components, it is clear that these elements or components are not limited by such terms. These terms are merely used to distinguish one element or component from another. Therefore, a first element or component mentioned below may be a second element or component within the technical scope of the present disclosure. Likewise, a lower element or component mentioned below may be an upper element or component within the technical scope of the present disclosure.

Embodiments of the present disclosure will hereinafter be described with reference to the accompanying drawings.

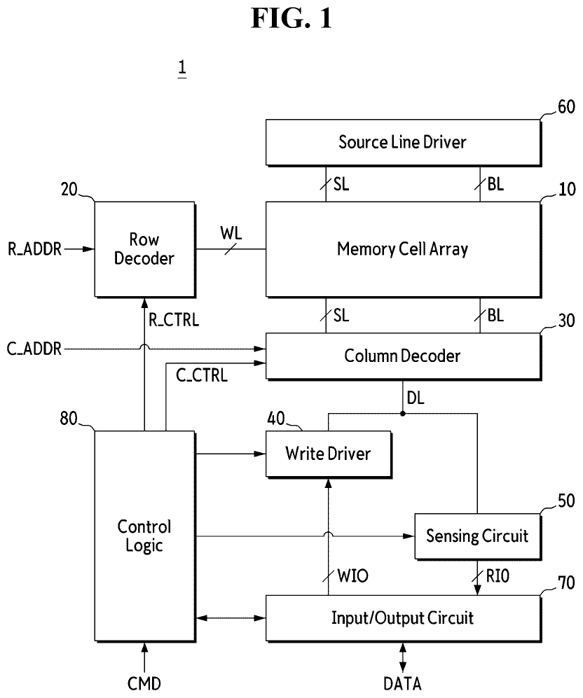

FIG. 1 is a block diagram for explaining a magnetic memory device according to one or more embodiments.

Referring to FIG. 1, a magnetic memory device 1 according to one or more embodiments may include a memory cell array 10, a row decoder 20, a column decoder 30, a write driver 40, a sensing circuit 50, a source line driver 60, an input/output circuit 70, and control logic 80.

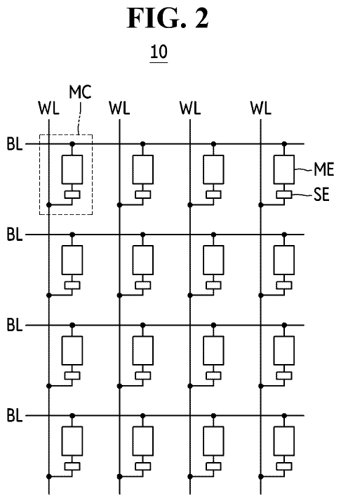

The memory cell array 10 may include a plurality of wordlines WL, a plurality of bitlines BL, and a plurality of source lines SL. Memory cells (MC of FIG. 2) may be connected at intersections of the wordlines WL and the bitlines BL. Each of the memory cells MC may be configured to store data. The memory cells MC may include, for example, variable resistance elements whose data values are determined based on resistance values, such as magnetic tunnel junction (MTJ) devices.

For example, the memory cells MC may include resistive random-access memories (ReRAMs), phase-change random-access memories (PRAM), ferroelectric random-access memories (FRAMs), and magnetic random-access memories (MRAMs), such as spin-transfer torque-MRAMs (STT-MRAMs), spin-transfer torque random-access memories (STT-RAMs or spin-RAMs), and spin-momentum transfer random-access memories (SMT-RAMs).

The row decoder 20 may select (or drive) a wordline WL connected to a memory cell MC in which a read or program operation is performed, based on a row address R_ADDR and a row control signal R_CTRL. The row decoder 20 may provide a driving voltage, input from the control logic 80, to the selected wordline WL.

The column decoder 30 may select a bitline BL or a source line SL connected to the memory cell MC in which a read or program operation is performed, based on a column address C_ADDR and a column control signal C_CTRL. The column decoder 30 may connect the selected bitline BL or source line SL to a data line DL.

The write driver 40 may drive a program voltage (or write current) to store write data in the memory cell MC selected by the row decoder 20 and the column decoder 30 during a program operation. For example, during the program operation, the write driver 40 may control the voltage of the data line DL based on write data I/O DATA input from the input/output circuit 70 through a write input/output line WIO, thereby storing the write data I/O DATA in the selected memory cell MC.

The sensing circuit 50 may detect a signal output through the data line DL during a read operation to determine the value of data stored in the memory cell MC. The sensing circuit 50 may be connected to the column decoder 30 through the data line DL and to the input/output circuit 70 through a read input/output line RIO. The sensing circuit 50 may input detected read data I/O DATA to the input/output circuit 70 through a read input/output line RIO.

The source line driver 60 may drive the source line SL to a specific voltage level under the control of the control logic 80. For example, the source line driver 60 may receive a voltage to drive the source line SL from the control logic 80.

The input/output circuit 70 may deliver the write data I/O DATA input from the outside to the write driver 40 and output the read data I/O DATA input from the sensing circuit 50 to the outside.

The control logic 80 may generally control the operation of the magnetic memory device 1. For example, the control logic 80 may control the row decoder 20, the column decoder 30, the write driver 40, the sensing circuit 50, the source line driver 60, and the input/output circuit 70. The control logic 80 may operate in response to commands CMD or control signals input from the outside. The commands CMD may include a read command and a write command.

FIG. 2 is a circuit diagram illustrating a memory cell array of the magnetic memory device according to one or more embodiments.

Referring to FIG. 2, the memory cell array 10 may include a plurality of memory cells MC.

The memory cells MC may be connected to a plurality of wordlines WL and a plurality of bitlines BL. Each of the memory cells MC may be connected between one of the wordlines WL and one of the bitlines BL. Memory cells MC connected to one bitline BL may be connected to respective wordlines WL. Similarly, memory cells MC connected to one wordline WL may be connected to respective bitlines BL. That is, by selecting one of the wordlines WL and one of the bitlines BL, a single memory cell MC may be selected.

Each memory cell MC may include a memory unit ME and a switching unit SE. The memory unit ME may be connected between a bitline BL and the switching unit SE. The switching unit SE may be connected between a wordline WL and the memory unit ME.

The memory unit ME may include a variable resistance unit capable of switching between two resistance states in response to an electrical signal applied to the memory unit ME. The memory unit ME may have a thin film structure that changes its electrical resistance based on a spin transfer process caused by current passing through the memory unit ME. The memory unit ME may have a thin film structure exhibiting magnetoresistance characteristics and may include at least one ferromagnetic material or at least one antiferromagnetic material.

The switching unit SE may be configured to selectively control the flow of charge through the memory unit ME. For example, the switching unit SE may include a field-effect transistor (FET), a diode, or a bipolar transistor.

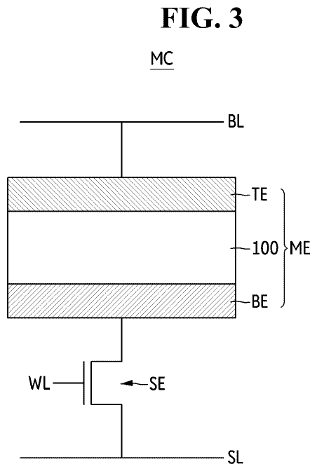

FIG. 3 is a schematic diagram illustrating a memory cell of the magnetic memory device according to one or more embodiments.

Referring to FIG. 3, a memory cell MC may include a memory unit ME and a switching unit SE.

The memory unit ME may include an MTJ 100, an upper electrode TE, and a lower electrode BE. The lower electrode BE may be disposed between the MTJ 100 and the switching unit SE. The upper electrode TE may be disposed between the MTJ 100 and a bitline BL. In other words, the MTJ 100 may be disposed between the lower electrode BE and the upper electrode TE. The sidewalls of the MTJ 100, the sidewalls of the upper electrode TE, and the sidewalls of the lower electrode BE may be aligned with each other.

Each of the upper electrode TE and the lower electrode BE may include a conductive metal nitride or a metal. For example, each of the upper electrode TE and the lower electrode BE may include tantalum (Ta), ruthenium (Ru), tantalum nitride (TaN), or a combination thereof.

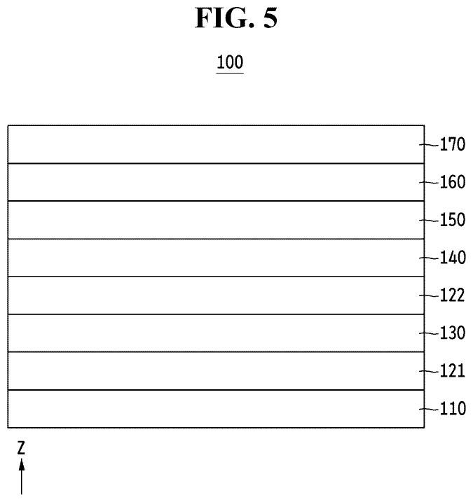

The MTJ 100 is illustrated as a single film, but this is merely an example. As will be described later with reference to FIG. 5, the MTJ 100 may include fixed layers (121 and 122 of FIG. 5), an antiparallel coupling layer (130 of FIG. 5), a tunnel barrier layer (140 of FIG. 5), and a free layer (150 of FIG. 5).

The fixed layers 121 and 122 of the MTJ 100 may have a fixed magnetization direction. The free layer 150 of the MTJ 100 may have a variable magnetization direction. Through this, the MTJ 100 may be used to store data based on its tunnel magnetoresistance characteristics.

Specifically, when the magnetization direction of the fixed layers 121 and 122 and the magnetization direction of the free layer 150 are parallel, electrons have a high probability of tunneling through the tunnel barrier layer 140, and the MTJ 100 may be in a low-resistance state. When the magnetization direction of the fixed layers 121 and 122 and the magnetization direction of the free layer 150 are antiparallel, the probability of tunneling decreases, and the MTJ 100 may be in a high-resistance state. Accordingly, the MTJ 100 may switch between two electrical resistance states, i.e., a low-resistance state and a high-resistance state. This characteristic allows the MTJ 100 to be used for storing data.

In one or more embodiments of the present disclosure, the magnetization direction of the fixed layers 121 and 122 and the free layer 150 of the MTJ 100 may be substantially perpendicular to the interface between the tunnel barrier layer 140 and the free layer 150. That is, the MTJ 100 may be a perpendicular MTJ.

In one or more embodiments of the present disclosure, the switching unit SE may include an FET. In one or more embodiments, a source line SL may be connected to a first source/drain of the switching unit SE, and the MTJ 100 may be connected to a second source/drain of the switching unit SE through the lower electrode BE. Additionally, a wordline WL may be connected to the gate of the switching unit SE. The MTJ 100 may be connected to the source line SL through the lower electrode BE and the switching unit SE, and to the bitline BL through the upper electrode TE.

In one or more embodiments of the present disclosure, the bitline BL and the source line SL may be interchangeable. That is, the MTJ 100 may be connected to the bitline BL through the lower electrode BE and the switching unit SE, and to the source line SL through the upper electrode TE. By controlling the voltage of the wordline WL, the switching unit SE may be turned on or off to selectively connect the MTJ 100 to the source line SL.

For a write operation of the memory cell MC, the switching unit SE may be turned on by applying a voltage to the wordline WL, and a write current may be applied between the bitline BL and the source line SL. At this time, the magnetization direction of the free layer 150 may be determined by the direction of the write current. Meanwhile, for a read operation of the memory cell MC, the switching unit SE may be turned on by applying a voltage to the wordline WL, and the data stored in the MTJ 100 may be determined by applying a read current from the bitline BL to the source line SL. Since the read current is much smaller than the write current, the magnetization direction of the free layer 150 may not change due to the read current.

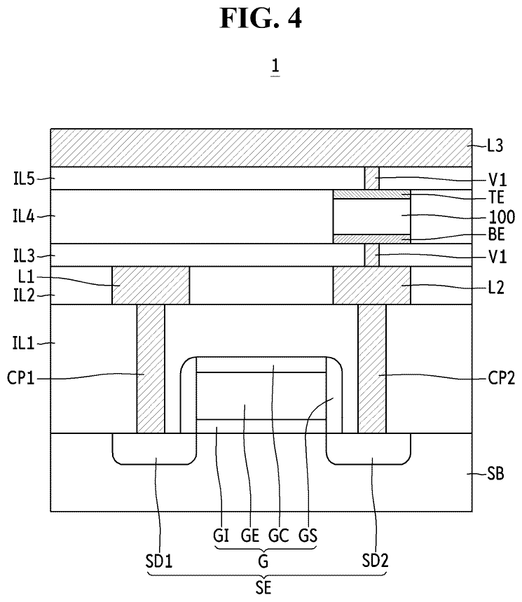

FIG. 4 is a schematic cross-sectional view illustrating the magnetic memory device according to one or more embodiments.

Referring to FIG. 4, the magnetic memory device 1 may include a substrate SB, a switching unit SE on the substrate SB, and an MTJ 100 connected to the switching unit SE.

The substrate SB may include a semiconductor material, such as a group IV semiconductor material, a group III-V semiconductor material, or a group II-VI semiconductor material. The group IV semiconductor material may include, for example, silicon (Si), germanium (Ge), or silicon-germanium (SiGe). The group III-V semiconductor material may include, for example, gallium arsenide (GaAs), indium phosphide (InP), gallium phosphide (GaP), indium arsenide (InAs), indium antimonide (InSb), or indium gallium arsenide (InGaAs). The group II-VI semiconductor material may include, for example, zinc telluride (ZnTe) or cadmium sulfide (CdS). The substrate SB may be a bulk wafer or an epitaxial layer.

The switching unit SE may include a gate structure G formed on the upper surface of the substrate SB, and a first source/drain region SD1 and a second source/drain region SD2 adjacent to both sides of the gate structure G. The gate structure G may include a gate insulating layer GI stacked on the upper surface of the substrate SB, a gate electrode layer GE on the gate insulating layer GI, and a gate capping layer GC on the gate electrode layer GE. The gate structure G may further include a gate spacer layer GS on the side surfaces of the gate insulating layer GI, the gate electrode layer GE, and the gate capping layer GC.

In one or more embodiments, the gate insulating layer GI may include an interfacial layer on the substrate SB and a high-k layer on the interfacial layer. The interfacial layer may include a low-k material with a dielectric constant of approximately 9 or less, such as silicon oxide (SiO₂), silicon nitride (SiN), or a combination thereof. The interfacial layer may be omitted. The high-k layer may include a material with a dielectric constant greater than that of SiO₂, for example, approximately 10 to 25. The high-k layer may include, for example, hafnium oxide (HfO₂), zirconium oxide (ZrO₂), aluminum oxide (Al₂O₃), or a combination thereof.

The gate electrode layer GE may include a metal, a metal nitride, a metal carbide, a semiconductor material, or a combination thereof. The metal may include titanium (Ti), tungsten (W), Ru, niobium (Nb), molybdenum (Mo), hafnium (Hf), nickel (Ni), cobalt (Co), platinum (Pt), ytterbium (Yb), terbium (Tb), dysprosium (Dy), erbium (Er), palladium (Pd), or a combination thereof. The metal nitride may include titanium nitride (TiN), TaN, or a combination thereof. The metal carbide may include titanium aluminum carbide (TiAlC). The semiconductor material may include polysilicon.

The gate capping layer GC may include, for example, SiN. The gate spacer layer GS may include, for example, SiO2, SiN, or a combination thereof.

Each of the first and second source/drain regions SD1 and SD2 may include a semiconductor material, such as a group III-V semiconductor material or a group II-VI semiconductor material. The group IV semiconductor material may include, for example, Si, Ge, or SiGe. The group III-V semiconductor material may include, for example, GaAs, InP, GaP, InAs, InSb, or InGaAs. The group II-VI semiconductor material may include, for example, ZnTe or CdS. For example, each of the first and second source/drain regions SD1 and SD2 may include Si. In one or more embodiments, the first and second source/drain regions SD1 and SD2 may be formed from the substrate SB. In other embodiments, each of the first and second source/drain regions SD1 and SD2 may include SiGe layers with different concentrations and an Si capping layer.

In one or more embodiments of the present disclosure, the magnetic memory device 1 may further include a first interlayer insulating layer IL1 covering the substrate SB and the switching unit SE. The first interlayer insulating layer IL1 may include, for example, SiO2, SiN, or a combination thereof. The magnetic memory device 1 may further include a first conductive line L1 and a second conductive line L2 on the first interlayer insulating layer IL1. The magnetic memory device 1 may further include a first contact plug CP1 that connects the first conductive line L1 to the first source/drain region SD1 and penetrates the first interlayer insulating layer IL1, and a second contact plug CP2 that connects the second conductive line L2 to the second source/drain region SD2 and penetrates the first interlayer insulating layer IL1. The first conductive line L1 may correspond to or be connected to the source line SL illustrated in FIG. 3. Each of the first conductive line L1, the second conductive line L2, the first contact plug CP1, and the second contact plug CP2 may include a metal and a metal barrier layer. The metal may include W, Ti, Ta, aluminum (Al), copper (Cu), silver (Ag), gold (Au), or a combination thereof. The metal barrier layer may include Ti, Ta, TiN, TaN, or a combination thereof.

In one or more embodiments of the present disclosure, the magnetic memory device 1 may further include a second interlayer insulating layer IL2, which is located on the first interlayer insulating layer IL1 and surrounds the side surfaces of the first and second conductive lines L1 and L2. The magnetic memory device 1 may further include a third interlayer insulating layer IL3 on the second interlayer insulating layer IL2. Each of the second and third interlayer insulating layers IL2 and IL3 may include SiO2, SiN, or a combination thereof.

In one or more embodiments of the present disclosure, a memory unit ME may be disposed on the third interlayer insulating layer IL3. In one or more embodiments, the magnetic memory device 1 may further include a first via V1 that penetrates the third interlayer insulating layer IL3 to connect the lower electrode BE to the second conductive line L2. The first via V1 may include a metal and a metal barrier layer. The metal may include W, Ti, Ta, Al, Cu, Ag, Au, or a combination thereof. The metal barrier layer may include Ti, Ta, TiN, TaN, or a combination thereof.

In one or more embodiments of the present disclosure, the magnetic memory device 1 may further include a fourth interlayer insulating layer IL4, which is located on the third interlayer insulating layer IL3 and surrounds the memory unit ME. In one or more embodiments, the magnetic memory device 1 may further include a fifth interlayer insulating layer IL5, which is located on the fourth interlayer insulating layer IL4. Each of the fourth and fifth interlayer insulating layers IL4 and IL5 may include SiO₂, SiN, or a combination thereof.

In one or more embodiments of the present disclosure, the magnetic memory device 1 may further include a third conductive line L3 on the fifth interlayer insulating layer IL5. The third conductive line L3 may correspond to or be connected to the bitline BL illustrated in FIG. 3. In one or more embodiments, the magnetic memory device 1 may further include a second via V2 that penetrates the fifth interlayer insulating layer IL5 to connect the third conductive line L3 to the upper electrode TE. Each of the third conductive line L3 and the second via V2 may include a metal and a metal barrier layer. The metal may include W, Ti, Ta, Al, Cu, Ag, Au, or a combination thereof. The metal barrier layer may include Ti, Ta, TiN, TaN, or a combination thereof.

FIG. 5 is a cross-sectional view illustrating an MTJ of the magnetic memory device according to one or more embodiments.

Referring to FIG. 5, the MTJ 100 of the magnetic memory device 1 may include a seed layer 110, a first fixed layer 121, an antiparallel coupling layer 130, a second fixed layer 122, a tunnel barrier layer 140, a free layer 150, a metal oxide layer 160, and a capping layer 170.

The seed layer 110 may be disposed on the lower electrode BE. The seed layer 110 may contact the lower electrode BE. The sidewalls of the seed layer 110 and the sidewalls of the lower electrode BE may be aligned with each other. Although not specifically illustrated, the MTJ 100 may further include a buffer layer disposed between the seed layer 110 and the lower electrode BE. The buffer layer may prevent the crystallinity of the lower electrode BE from affecting the crystallinity of the seed layer 110, the fixed layers 121 and 122, the tunnel barrier layer 140, and the free layer 150.

The seed layer 110 may be configured to allow the fixed layers 121 and 122, the tunnel barrier layer 140, and the free layer 150 to have a desirable crystal structure. The seed layer 110 may include, for example, nickel-chromium (NiCr), cobalt-iron-boron (CoFeB), magnesium (Mg), Ta, Ru, or a combination thereof.

The fixed layers 121 and 122 may have a fixed magnetization direction. The fixed magnetization direction may be a vertical direction (e.g., a +Z-axis direction) or the opposite direction to the vertical direction (e.g., a −Z-axis direction).

The fixed layers 121 and 122 may include the first fixed layer 121 on the seed layer 110 and the second fixed layer 122 on the antiparallel coupling layer 130. The first fixed layer 121 may refer to a hard bias stack. The second fixed layer 122 may refer to a reference layer.

Each of the first and second fixed layers 121 and 122 may be ferromagnetic. Each of the first and second fixed layers 121 and 122 may have a fixed magnetization direction. However, the magnetization direction of the second fixed layer 122 may be opposite to that of the first fixed layer 121. For example, while the magnetization direction of the first fixed layer 121 is the vertical direction (or the +Z-axis direction), the magnetization direction of the second fixed layer 122 may be the opposite direction to the vertical direction (or the −Z-axis direction). Each of the first and second fixed layers 121 and 122 may include at least one of Co, Ni, or iron (Fe). For example, each of the first and second fixed layers 121 and 122 may include cobalt-nickel (CoNi), CoFeB, cobalt-iron-molybdenum (CoFeMo), cobalt-chromium (CoCr), cobalt-iron (CoFe), cobalt-platinum (CoPt), iron boride (FeB), cobalt boride (CoB), cobalt-iron-aluminum (CoFeAl), or a combination thereof.

The antiparallel coupling layer 130 may be disposed on the upper surface of the first fixed layer 121. The antiparallel coupling layer 130 may contact the upper surface of the first fixed layer 121. The antiparallel coupling layer 130 may be disposed between the first and second fixed layers 121 and 122. The upper surface of the antiparallel coupling layer 130 may contact the second fixed layer 122. The sidewalls of the antiparallel coupling layer 130 may be aligned with the sidewalls of the first and second fixed layers 121 and 122. The antiparallel coupling layer 130 may include, for example, iridium (Ir), Ru, or a combination thereof.

The antiparallel coupling layer 130 may include a synthetic antiferromagnetic (SAF) layer. The antiparallel coupling layer 130 may couple the fixed magnetization directions of the first and second fixed layers 121 and 122 in an antiparallel manner. That is, the antiparallel coupling layer 130 may cancel out the magnetic fields generated by the first and second fixed layers 121 and 122. This can minimize the influence of the magnetic fields generated by the first and second fixed layers 121 and 122 on the free layer 150 that will be described later.

The tunnel barrier layer 140 may be disposed on the fixed layers 121 and 122. The tunnel barrier layer 140 may separate the fixed layers 121 and 122 from the free layer 150. The tunnel barrier layer 140 may include Al₂O₃, magnesium oxide (MgO), magnesium aluminum oxide (MgAlO), HfO2, ZrO2, zinc oxide (ZnO₂), titanium oxide (TiO₂), or a combination thereof. Although not specifically illustrated, the tunnel barrier layer 140 may include multiple layers. For example, the tunnel barrier layer 140 may have a stacked structure such as Mg/MgO, MgO/Mg, MgO/MgAlO, MgAlO/MgO, Mg/MgAlO/Mg, MgO/MgAlO/MgO, or MgAlO/MgO/MgAlO.

The free layer 150 may be disposed on the tunnel barrier layer 140. The free layer 150 may contact the tunnel barrier layer 140. The free layer 150 may contact the upper surface of the tunnel barrier layer 140. The free layer 150 may have the characteristic of being magnetized perpendicularly (or in the +Z-axis direction) or in the opposite direction to the vertical direction (or in the −Z-axis direction) by magnetic anisotropy induced due to the junction of the free layer 150 and the tunnel barrier layer 140. The variable magnetization direction of the free layer 150 may be parallel to or antiparallel with the fixed magnetization direction of the fixed layers 121 and 122.

For example, when the magnetization directions of the free layer 150 and the fixed layers 121 and 122 are parallel in the vertical direction (or the +Z-axis direction), electrons have a higher probability of tunneling through the tunnel barrier layer 140, and the MTJ 100 may be in a low-resistance state. When the magnetization direction of the fixed layers 121 and 122 is in the vertical direction (or the +Z-axis direction) and the magnetization direction of the free layer 150 is in the opposite direction to the vertical direction (or the −Z-axis direction), the probability of tunneling through the tunnel barrier layer 140 decreases, and the MTJ 100 may be in a high-resistance state. Accordingly, the MTJ 100 may switch between two electrical resistance states, i.e., a low-resistance state and a high-resistance state. Due to this characteristic, the MTJ 100 may be used to store data.

The free layer 150 may include Co, Fe, CoB, FeB, CoFe, CoFeB, cobalt oxide (CoO), iron oxide (FeO), cobalt-iron oxide (CoFeO), or a combination thereof.

The metal oxide layer 160 may be disposed on the free layer 150. The metal oxide layer 160 may contact the free layer 150. The metal oxide layer 160 may contact the upper surface of the free layer 150.

The metal oxide layer 160 may include first and second metal materials (metals) that are different from each other. The first metal material may have a stronger bonding affinity with boron (B) compared to the second metal material. The second metal material may have a stronger bonding affinity with oxygen (O) compared to the first metal material.

For example, the first metal material may include at least one of Ta, Mo, and W. The first metal material may have a body-centered cubic (BCC) structure.

For example, the second metal material may include at least one of Fe, vanadium (V), manganese (Mn), chromium (Cr), Ti, Al, Mg, lithium (Li), and calcium (Ca).

In the metal oxide layer 160, the content of the second metal material may be at least 5% relative to the content of the first metal material. For example, when the first metal material is Ta and the second metal material is Fe, the content of Fe in the metal oxide layer 160 may be at least about 5%, while the content of Ta may be about 28%. In this case, the content of Fe may be approximately 17.58% relative to the content of Ta. However, the technical scope of the present disclosure is not limited to this.

In the metal oxide layer 160, the content of the second metal material may be less than that of the first metal material. For example, when the first metal material is Ta and the second metal material is Fe, the content of Fe may be less than that of Ta.

The O content in the metal oxide layer 160 may be greater than the O content in the free layer 150.

The metal oxide layer 160 may further include a third metal material different from the first and second metal materials. In the metal oxide layer 160, the content of the second metal material may be greater than that of the third metal material. For example, the third metal material may include at least one of Co or Mg. For example, when the second metal material is Co, the content of Co in the metal oxide layer 160 may be 3% or less.

The capping layer 170 may be disposed on the metal oxide layer 160. The capping layer 170 may be disposed between the metal oxide layer 160 and the upper electrode TE (see FIG. 4). The capping layer 170 may contact the metal oxide layer 160.

The capping layer 170 may be configured to protect the MTJ 100 in subsequent processes after the MTJ 100 is manufactured. The capping layer 170 may include a metal or a metal nitride. The metal may include Ru and Ta. The metal nitride may include TiN, TaN, aluminum nitride (AlN), zirconium nitride (ZrN), niobium nitride (NbN), molybdenum nitride (MoN), or a combination thereof. Contrary to what is illustrated, the capping layer 170 may include multiple layers.

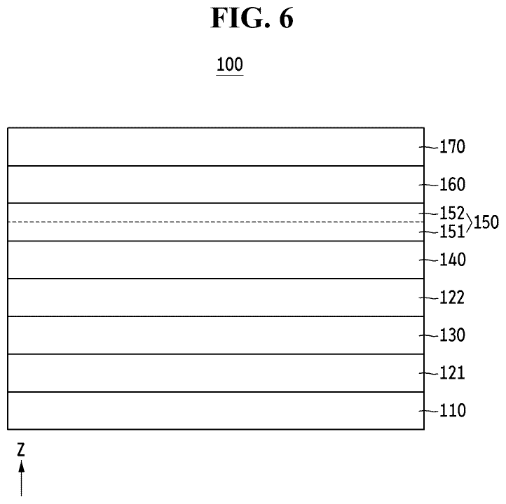

FIG. 6 is a cross-sectional view illustrating an MTJ of a magnetic memory device according to one or more embodiments. For convenience of explanation, redundant content described with reference to FIGS. 1 through 5 may be omitted.

Referring to FIG. 6, a free layer 150 may include a first free layer 151 on the tunnel barrier layer 140 and a second free layer 152 between the first free layer 151 and a metal oxide layer 160.

The first free layer 151 may include at least one of Co, Fe, and B. For example, the first free layer 151 may include CoFeB. The second free layer 152 may include Fe.

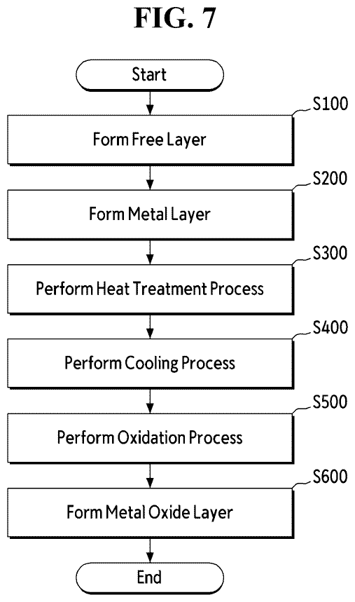

FIG. 7 is a flowchart illustrating a method for manufacturing a magnetic memory device according to one or more embodiments. For convenience of explanation, redundant content described with reference to FIGS. 1 through 6 may be omitted.

First, the seed layer 110 of FIG. 5 may be provided. The first fixed layer 121 of FIG. 5 may be formed on the seed layer 110. The antiparallel coupling layer 130 of FIG. 5 including an SAF layer may be formed on the first fixed layer 121. The second fixed layer 122 of FIG. 5 may be formed on the antiparallel coupling layer 130. The tunnel barrier layer 140 of FIG. 5 may be formed on the second fixed layer 122 of FIG. 5.

Referring to FIG. 7, the free layer 150 of FIG. 5 may be formed on the tunnel barrier layer 140 (S100). The free layer 150 may include B. In other words, the tunnel barrier layer 140 may be provided, and the free layer may be formed thereon.

In one or more embodiments, a fixed layer may be provided, and the tunnel barrier layer formed thereon. The method may further include forming an antiparallel coupling layer comprising a synthetic antiferromagnetic (SAF) layer on the fixed layer.

Thereafter, a metal layer may be formed on the free layer 150 (S200). The metal layer may include an alloy of a first metal material and a second metal material. The first metal material may have a stronger bonding affinity with B than the second metal material, and the second metal material may have a stronger bonding affinity with O than the first metal material.

In one or more embodiments, the metal layer is an iron tantalum (FeTa) layer, and the method comprises forming the FeTa layer on the free layer.

The first metal material may include at least one of Ta, Mo, or W. The second metal material may include at least one of Fe, V, Mn, Cr, Ti, Al, Mg, Li, or Ca.

Thereafter, a heat treatment process may be performed (S300). The heat treatment process may be performed after forming the metal layer (or FeTa layer) and before performing an oxidation process that will be described later. During the heat treatment process, B in the free layer 150 may diffuse into the metal layer. Additionally, the heat treatment process may crystallize the free layer 150.

Thereafter, a cooling process may be performed (S400). The cooling process may be performed after the heat treatment process and before the oxidation process.

Thereafter, the oxidation process may be performed (S500). Accordingly, the metal oxide layer 160 of FIG. 5 including an oxide of the second metal material may be formed. The oxidation process may form an oxide layer on the FeTa layer, the oxide layer including Fe, Ta, and O. In one or more embodiments, the method further includes forming a capping layer on the oxide layer, after the oxidation process.

An MTJ device according to one or more embodiments of the present disclosure may be manufactured by forming a metal layer, which is an alloy of the first and second metal materials, on the free layer 150. In one or more embodiments, by not only using the first metal material, but also using the second metal material, which has a strong bonding affinity with O, additional oxidation of the free layer 150 can be prevented. Accordingly, the effective thickness of the free layer 150 can be ensured more reliably compared to a case where only the first metal material is used.

As a result, device resistance can be reduced, resistance variation can be improved, and tunneling magnetoresistance (TMR) characteristics can be enhanced. Consequently, a magnetic memory device with improved reliability and performance can be formed.

Thereafter, although not specifically illustrated, the capping layer 170 of FIG. 5 may further be formed on the metal oxide layer 160.

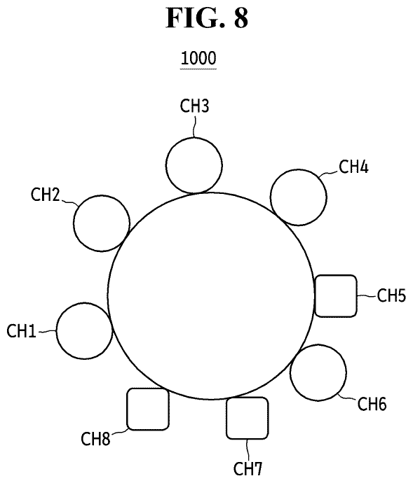

FIG. 8 is a schematic diagram illustrating a system for manufacturing a magnetic memory device according to one or more embodiments. For convenience of explanation, redundant content described with reference to FIGS. 1 through 7 may be omitted.

Referring to FIG. 8, a system 1000 may include a plurality of first through eighth chambers CH1 through CH8. According to one or more embodiments, processes may be performed in situ in the first through eighth chambers CH1 through CH8.

In the first chamber CH1, the seed layer 110 of FIG. 5 may be formed, and the first fixed layer 121 of FIG. 5 may be formed on the seed layer 110.

In the second chamber CH2, the antiparallel coupling layer 130 of FIG. 5 may be formed, and the second fixed layer 122 of FIG. 5 may be formed on the antiparallel coupling layer 130.

In the third chamber CH3, the tunnel barrier layer 140 of FIG. 5 may be formed.

In the fourth chamber CH4, the free layer 150 of FIG. 5 may be formed, and a metal layer may be formed on the free layer 150. The metal layer may include first and second metal materials as described above. The first metal material may have a stronger bonding affinity with B compared to the second metal material, and the second metal material may have a stronger bonding affinity with O compared to the first metal material.

The first metal material may include at least one of Ta, Mo, or W. The second metal material may include at least one of Fe, V, Mn, Cr, Ti, Al, Mg, Li, or Ca.

In the fifth chamber CH5, a heat treatment process may be performed. As a result of the heat treatment process, B in the free layer 150 may diffuse into the metal layer.

In the sixth chamber CH6, the capping layer 170 of FIG. 5 may be formed. The capping layer 170 may be formed on the metal oxide layer 160 of FIG. 5.

In the seventh chamber CH7, a cooling process may be performed.

In the eighth chamber CH8, an oxidation process may be performed. Accordingly, the metal oxide layer 160 may be formed.

Although the embodiments of the present disclosure have been described with reference to the accompanying drawings, the present disclosure is not limited to these embodiments and may be manufactured in various other forms. Those skilled in the art will understand that the technical scope or essential characteristics of the present disclosure can be modified and implemented in other specific forms without departing from the spirit of the invention. Therefore, the embodiments described above should be understood as being illustrative in all respects and not limiting.

What is claimed is:

1. A method for manufacturing a magnetic memory device, comprising:
providing a seed layer;
forming a fixed layer on the seed layer;
forming an antiparallel coupling layer including a synthetic antiferromagnetic (SAF) layer, on the fixed layer;
forming a tunnel barrier layer;
forming a free layer on the tunnel barrier layer;
forming a metal layer including a first metal and a second metal, on the free layer; and
performing an oxidation process to form a metal oxide layer including an oxide of the second metal,
wherein the first metal has a stronger bonding affinity with boron (B) than the second metal, and
wherein the second metal has a stronger bonding affinity with oxygen (O) than the first metal.

2. The method of claim 1, further comprising:
performing a heat treatment process after the forming the metal layer and before the performing the oxidation process.

3. The method of claim 2, further comprising:
performing a cooling process after the performing the heat treatment process and before the performing the oxidation process.

4. The method of claim 1, wherein the first metal includes at least one of tantalum (Ta), molybdenum (Mo), or tungsten (W).

5. The method of claim 1, wherein the second metal includes at least one of iron (Fe), vanadium (V), manganese (Mn), chromium (Cr), titanium (Ti), aluminum (Al), magnesium (Mg), lithium (Li), or calcium (Ca).

6. The method of claim 1,
wherein the free layer includes a first free layer on the tunnel barrier layer and a second free layer between the first free layer and the metal oxide layer,
wherein the first free layer includes at least one of cobalt (Co), Fe, or B, and
wherein the second free layer includes Fe.

7. The method of claim 1, wherein the tunnel barrier layer includes Mg.

8. The method of claim 1,
wherein the fixed layer includes Co, and
wherein the antiparallel coupling layer includes iridium (Ir).

9. The method of claim 1, further comprising:
forming a capping layer on the metal oxide layer,
wherein the capping layer includes ruthenium (Ru).

10. A method for manufacturing a magnetic tunnel junction (MTJ), comprising:
providing a tunnel barrier layer;
forming a free layer on the tunnel barrier layer;
forming an iron tantalum (FeTa) layer on the free layer; and
performing an oxidation process to form an oxide layer on the FeTa layer, the oxide layer including iron (Fe), tantalum (Ta), and oxygen (O).

11. The method of claim 10, wherein a content of the Fe in the oxide layer is at least 5% of a content of the Ta in the oxide layer.

12. The method of claim 10, further comprising:
performing a heat treatment process after the forming the FeTa layer and before the performing the oxidation process.

13. The method of claim 12, further comprising:
performing a cooling process after the performing the heat treatment process and before the performing the oxidation process.

14. The method of claim 10, wherein the tunnel barrier layer includes Mg.

15. The method of claim 10, further comprising:
providing a fixed layer; and
forming the tunnel barrier layer on the fixed layer.

16. The method of claim 15, further comprising:
forming an antiparallel coupling layer including a synthetic antiferromagnetic (SAF) layer, on the fixed layer;
wherein the fixed layer includes Co, and
wherein the antiparallel coupling layer includes iridium (Ir).

17. The method of claim 10, further comprising:
forming a capping layer on the oxide layer,
wherein the capping layer includes ruthenium (Ru).

18. A method for manufacturing a magnetic memory device, comprising:
providing a seed layer;
forming a first fixed layer on the seed layer;
forming an antiparallel coupling layer including a synthetic antiferromagnetic (SAF) layer, on the first fixed layer;
forming a second fixed layer on the antiparallel coupling layer;
forming a tunnel barrier layer on the second fixed layer;
forming a free layer including boron (B), on the tunnel barrier layer;
forming a metal layer including a first metal and a second metal, on the free layer, wherein the first metal has a stronger bonding affinity with the boron (B) than the second metal and the second metal has a stronger bonding affinity with oxygen (O) than the first metal;
performing a heat treatment process to diffuse the B from the free layer into the metal layer; and
performing an oxidation process to form a metal oxide layer including an oxide of the second metal.

19. The method of claim 18, further comprising:
forming a capping layer on the metal oxide layer.

20. The method of claim 18,
wherein the first metal includes at least one of tantalum (Ta), molybdenum (Mo), or tungsten (W), and
wherein the second metal includes at least one of iron (Fe), vanadium (V), manganese (Mn), chromium (Cr), titanium (Ti), aluminum (Al), magnesium (Mg), lithium (Li), or calcium (Ca).
